(19) United States
(12) Patent Application Publication
(10) Pub. No.: US 2025/0240928 A1
(43) Pub. Date: Jul. 24, 2025

(54) LIQUID DISTRIBUTION AND COLLECTION MODULE

(71) Applicant: SHENZHEN ENVICOOL TECHNOLOGY CO., LTD., Shenzhen (CN)

(72) Inventors: Xiaoxin XU, Shenzhen (CN); Xiaolei AI, Shenzhen (CN); Zhen XIONG, Shenzhen (CN); Xiaojin CHENG, Shenzhen (CN)

(73) Assignee: SHENZHEN ENVICOOL TECHNOLOGY CO., LTD., Shenzhen (CN)

(21) Appl. No.: 18/806,126

(22) Filed: Aug. 15, 2024

(30) Foreign Application Priority Data
Jan. 19, 2024 (CN) 202410084559.0

(51) Int. Cl. H05K 7/20

(52) U.S. Cl. CPC H05K 7/20772

(57) ABSTRACT

A liquid distribution and collection module includes a liquid distributor and collector, a liquid supply pipe and a liquid return pipe connected to the liquid distributor and collector. The liquid distribution and collection module further includes an outer frame, in which an accommodation cavity and a liquid collection cavity are provided. The liquid distributor and collector, at least part of the liquid supply pipe, and at least part of the liquid return pipe are accommodated in the accommodation cavity, the liquid collection cavity is in communication with the accommodation cavity, to allow a leaked liquid in the accommodation cavity to be gathered into the liquid collection cavity.

### CROSS REFERENCE TO RELATED APPLICATIONS

This application claims the priority to Chinese Patent Application No. 202410084559.0 titled “LIQUID DISTRIBUTION AND COLLECTION MODULE”, filed with the China National Intellectual Property Administration on Jan. 19, 2024, which is incorporated herein by reference in its entirety.

### FIELD

The present application relates to the technical field of cooling-plate liquid cooling, and in particular to a liquid distribution and collection module.

### BACKGROUND

At present, the cooling-plate liquid cooling technology has become a prevailing cooling technology for servers.

In the existing system, the cooling-plate liquid cooling device includes cooling plates, a liquid distributor and collector, and liquid supply pipes and liquid return pipes connected between the liquid distributor and collector and the cooling plates. The liquid distributor and collector is use as a liquid supply and collection device to connect the liquid supply pipes and liquid return pipes. The cooling-plate liquid cooling device uses the cooling plate to contact the main board and other heating components, and distribute and supply a liquid cooling medium to the cooling plates through the liquid distributor and collector, to realize heat dissipation of the main board.

It is found by the inventor that there are at least the following problems in the conventional technology. In order to reduce the maintenance time and cost for the cooling-plate liquid cooling device, quick couplings are often used for connection among the liquid supply pipes, the liquid return pipes, and the liquid distributor and collector. The defects existing in a connection position of the quick couplings cause a leakage risk of the liquid cooling medium, which may pose a significant threat to the hardware and the data security of the server.

Therefore, a technical problem to be solved by those skilled in the art is to avoid the significant risks to the hardware and the data security of server caused by the leakage of liquid cooling medium at the connection positions of the joints of the liquid distributor and collector.

### SUMMARY

An object of the present application is to provide a liquid distribution and collection module, which can solve the problem of the significant risks to the hardware and the data security of server caused by the leakage of liquid cooling medium at the connection positions of joints of the liquid distributor and collector.

In order to achieve the above object, a liquid distribution and collection module is provided in the present application, including a liquid distributor and collector, and a liquid supply pipe and a liquid return pipe connected to the liquid distributor and collector, where the liquid distribution and collection module further includes an outer frame, and where an accommodation cavity and a liquid collection cavity are provided in the outer frame, the liquid distributor and collector, at least part of the liquid supply pipe, and at least part of the liquid return pipe are accommodated in the accommodation cavity, and the liquid collection cavity is in communication with the accommodation cavity, so that a leaked liquid in the accommodation cavity is gathered into the liquid collection cavity.

In some embodiments, the liquid distribution and collection module further includes a support structure being connected to the outer frame, where the support structure is configured to support the outer frame, to make a guide slope configured for guiding the leaked liquid be formed inside the outer frame.

In some embodiments, the outer frame includes a liquid collection housing, and the liquid collection cavity is formed in the liquid collection housing, where the liquid collection housing includes a bottom plate and an enclosing plate assembly, wherein the guide slope is provided on the bottom plate; the enclosing plate assembly is arranged on the bottom plate, and the enclosing plate assembly is configured to enclose an outer periphery of the guide slope, to form the liquid collection cavity.

In some embodiments, the liquid collection housing further includes a baffle plate, and the baffle plate and the enclosing plate assembly together form a closed fence structure on the bottom plate, to prevent the leaked liquid from splashing out of the outer frame.

In some embodiments, the outer frame further includes a cover being connected to the liquid collection housing, where the cover includes a positioning plate assembly, the liquid supply pipe and the liquid return pipe pass through the positioning plate assembly to be positioned by the positioning plate assembly.

In some embodiments, the positioning plate assembly includes a first positioning plate and a second positioning plate, where the first positioning plate is provided with a first positioning groove and a second positioning groove each having an opening facing upward; and the second positioning plate is provided with a third positioning groove and a fourth positioning groove each having an opening facing downward, and the second positioning plate and the first positioning plate abut against each other, and the first positioning groove and the third positioning groove are staggered with respect to each other to form a liquid-supply positioning structure for positioning the liquid supply pipe, and the second positioning groove and the fourth positioning groove are staggered with respect to each other to form a liquid-return positioning structure for positioning the liquid return pipe.

In some embodiments, the outer frame is further provided with an observation window, and an inner wall of the liquid collection housing is provided with a liquid level indication line, and the observation window is configured to observe the liquid level indication line at a position of the leaked liquid inside the liquid collection housing is positioned.

In some embodiments, the observation window is rotatably connected to a top of the outer frame, and the observation window is configured to be flipped toward an outside of the outer frame to form a maintenance opening for mounting and removing the liquid supply pipe and the liquid return pipe.

In some embodiments, the liquid collection housing is embodied as a liquid collection trough, and the liquid level indication line is provided on an inner wall of the liquid collection trough and includes a warning scale line.

In some embodiments, the liquid distribution and collection module further includes a liquid suction tube, a liquid suction assembly, a leakage detection sensor, and a control assembly, where the control assembly is electrically connected to the leakage detection sensor and the liquid suction assembly, and the liquid suction assembly is connected to the liquid collection trough via the liquid suction tube, so as to control the liquid suction assembly to start to draw the leaked liquid in the liquid collection trough when the leaked liquid exceeds the warning scale line.

Compared with the conventional technology, the liquid distribution and collection module provided in the present application includes a liquid distributor and collector, which is connected to a liquid supply pipe and a liquid return pipe. The liquid distribution and collection module further includes an outer frame, which is provided with an accommodation cavity and a liquid collection cavity therein. Specifically, the liquid distributor and collector, at least part of the liquid supply pipe, and at least part of the liquid return pipe are accommodated in the accommodation cavity, the liquid collection cavity is in communication with the accommodation cavity, so that a leaked liquid that occurs in the accommodation cavity is gathered into the liquid collection cavity. It can be understood that, on one hand, since the liquid distributor and collector, the at least part of the liquid supply pipe, and the at least part of the liquid return pipe are accommodated in the accommodation cavity, leakage points at a joint between the liquid distributor and collector and the liquid supply pipe and a joint between the liquid distributor and collector and the liquid return pipe are all located in the accommodation cavity, which ensures that the leaked liquid at the positions of the liquid distributor and collector can be collected in the outer frame; on the other hand, the leaked liquid in the accommodation cavity can be gathered into the liquid collection cavity, which further ensures that the leaked liquid at the position of the liquid distributor and collector will not leaked out to affect the hardware and data security of the server. Compared with the conventional arrangement, the liquid distribution and collection module according to the present application is additionally provided with the outer frame that can collect the leaked liquid at the position of the liquid distributor and collector, which solves the problem that the leakage of the liquid cooling medium at pipeline joints of the liquid distributor and collector causes a significant risk to the hardware and the data security of the server, and thereby improving the operation safety and stability of the server.

### BRIEF DESCRIPTION OF THE DRAWINGS

For more clearly illustrating embodiments of the present application or the technical solutions in the conventional technology, drawings referred to describe the embodiments or the conventional technology will be briefly described hereinafter. Apparently, the drawings in the following description are only some examples of the present application, and for those skilled in the art, other drawings may be obtained based on these drawings without any creative efforts.

FIG. 1 is a schematic view showing a liquid distribution and collection module according to an embodiment of the present application being assembled to a server;

FIG. 2 is a top view of FIG. 1;

FIG. 3 is a cross-sectional view of the liquid distribution and collection module according to an embodiment of the present application;

FIG. 4 is a schematic view showing the overall structure of an outer frame of the liquid distribution and collection module in FIG. 3;

FIG. 5 is a right side view of the outer frame in FIG. 4;

FIG. 6 is a bottom view of the outer frame in FIG. 4;

FIG. 7 is a front view of the outer frame in FIG. 4; and

FIG. 8 is a cross-sectional view of the outer frame in FIG. 4.

### REFERENCE NUMERALS

| | |
|---|---|
| 1 | liquid distribution and collection module, |
| 11 | liquid distributor and collector, |
| 12 | liquid supply pipe, |
| 13 | liquid return pipe, |
| 14 | outer frame, |
| 15 | accommodation cavity, |
| 16 | liquid collection cavity, |
| 17 | support structure, |
| 141 | cover, |
| 142 | liquid collection housing, |
| 1411 | positioning plate assembly, |
| 1412 | observation window, |
| 1421 | bottom plate, |
| 1422 | enclosing plate assembly, |
| 1423 | baffle plate, |
| 14211 | guide slope. |

### DETAILED DESCRIPTION OF THE EMBODIMENTS

Technical solutions according to the embodiments of the present application will be described clearly and completely as follows in conjunction with the accompany drawings in the embodiments of the present application. It is obvious that the described embodiments are only a part of the embodiments according to the present application, rather than all of the embodiments. All the other embodiments obtained by those skilled in the art based on the embodiments in the present application without any creative work belong to the scope of protection of the present application.

For those skilled in the art to better understand the solution of the present application, the present application is described in detail hereinafter in conjunction with the drawings and specific embodiments.

It should be noted that the orientation terms such as “upper”, “lower”, “front”, “rear”, “left”, and “right” in this application are defined based on the drawings of the specification and the orientation in actual operation.

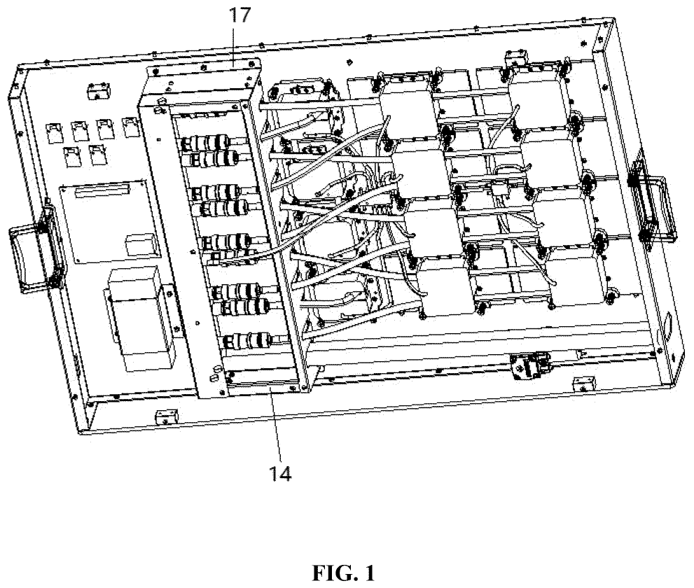

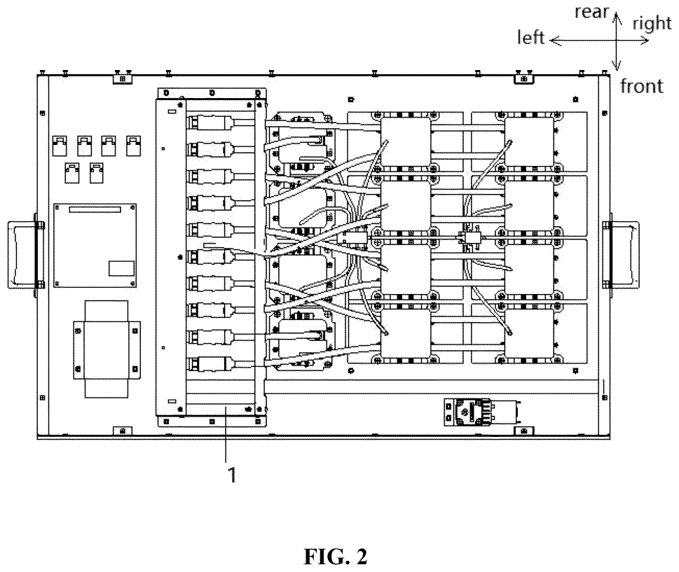

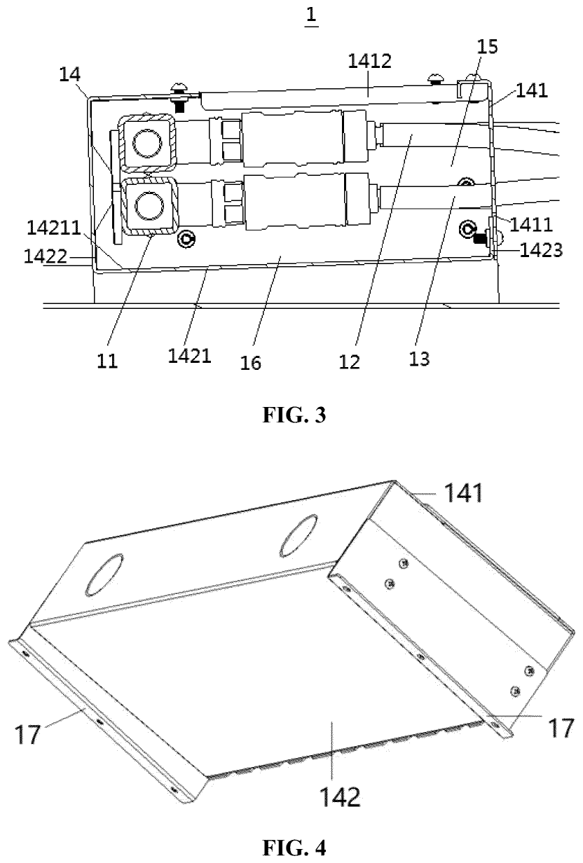

Referring to FIG. 1, FIG. 2 and FIG. 3, a liquid distribution and collection module 1 is provided in an embodiment of the present application, including a liquid distributor and collector 11, and a liquid supply pipe 12 and a liquid return pipe 13 are connected to the liquid distributor and collector 11. Specifically, multiple liquid supply pipes 12 and multiple liquid return pipes 13 are connected to the liquid distributor and collector 11 in pairs, where the liquid supply pipe 12 and the liquid return pipe 13 are connected in pairs. Both the liquid supply pipe 12 and the liquid return pipe 13 are connected to a cooling plate. The liquid supply pipe 12 is used to supply a liquid cooling medium distributed by the liquid distributor and collector 11 to the cooling plate, and the liquid return pipe 13 is used to return the liquid cooling medium back to the liquid distributor and collector 11 after heat exchange in the cooling plate. The number of the liquid supply pipes 12 and the liquid return pipes 13 may be determined according to the working components of the server that require to be cooled, which is not limited in this embodiment.

Referring to FIG. 4, the liquid distribution and collection module 1 further includes an outer frame 14, where an accommodation cavity 15 and a liquid collection cavity 16 are provided in the outer frame 14.

Taking a pair of liquid supply pipe 12 and liquid return pipe 13 connected to the liquid distributor and collector 11 as an example, the liquid distributor and collector 11, at least part of the liquid supply pipe 12, and at least part of the liquid return pipe 13 are accommodated in the accommodation cavity 15, and the liquid collection cavity 16 is in communication with the accommodation cavity 15, so that a leaked liquid that emerges in the accommodation cavity 15 can be gathered into the liquid collection cavity 16.

It can be understood that, due to the fact that the liquid distributor and collector 11, the at least part of the liquid supply pipe 12, and the at least part of the liquid return pipe 13 are accommodated in the accommodation cavity 15, leakage points occurring at a joint between the liquid distributor and collector 11 and the liquid supply pipe 12 and a joint between the liquid distributor and collector 11 and the liquid return pipe 13 are all located in the accommodation cavity 15, which ensures that all the liquid leaked from the liquid distributor and collector 11 can be collected by the outer frame 14.

It should be noted that both the liquid supply pipe 12 and the liquid return pipe 13 are connected to the liquid distributor and collector 11 through a quick coupling. Based on this, a joint position among the liquid distributor and collector 11, the liquid supply pipe 12, and the corresponding quick coupling and a joint position among the liquid distributor and collector 11, the liquid return pipe 13, and the corresponding quick coupling are all located inside the accommodation cavity 15, which ensures that no liquid leaks outside the outer frame 14.

In this way, the leaked liquid emerging in the accommodation cavity 15 can be gathered into the liquid collection cavity 16, which further ensures that the leaked liquid at the position of the liquid distributor and collector 11 will not leaked out to affect the hardware and the data security of the server.

Compared with the conventional technology, in the liquid distribution and collection module 1 according to the embodiment of the present application, the outer frame 14 is additionally provided to collect the leaked liquid at the position of the liquid distributor and collector 11, which solves the problem that the leakage of the liquid cooling medium at pipeline joints of the liquid distributor and collector 11 causes a significant risk to the hardware and the data security of the server, and thereby improving the operation safety and stability of the server.

In order to guide the leaked liquid after entering the liquid collection cavity 16 to facilitate liquid collection, a guide slope 14211 may be further provided inside the outer frame 14, where the guide slope 14211 is inclined towards one side, so that the leaked liquid that entered the liquid collection cavity 16 can flow down along the guide slope 14211 to be collected.

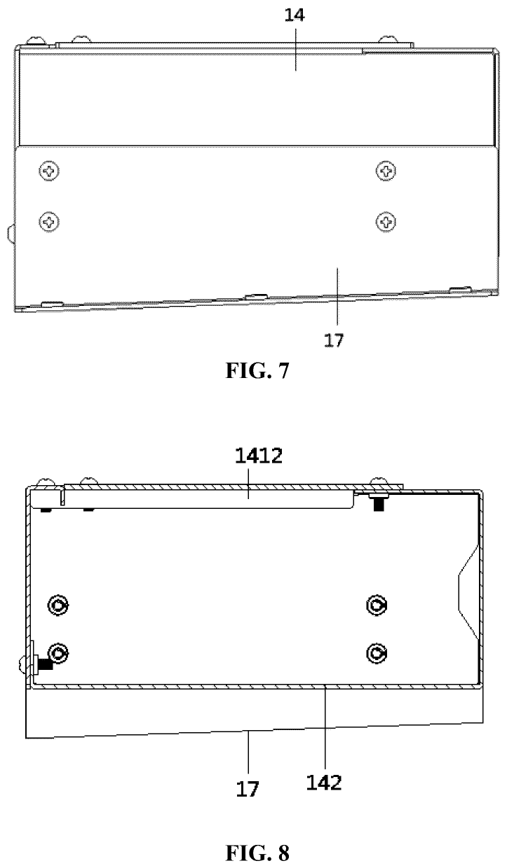

With reference to FIG. 6, FIG. 7 and FIG. 8, the liquid distribution and collection module 1 further includes a support structure 17, which is connected to the outer frame 14. The support structure 17 is used to support the outer frame 14, so that the guide slope 14211 for guiding the leaked liquid can be formed inside the outer frame 14.

In an embodiment, the support structure 17 may be of a supporting leg or a bent plate structure, such as an L-shaped bent plate.

As shown in FIG. 4, the outer frame 14 includes a cover 141 and a liquid collection housing 142 located at a bottom thereof, and the liquid collection cavity 16 is located inside the liquid collection housing 142.

As can be seen, in order to facilitate liquid collection, the liquid collection housing 142 is provided to form a lower portion of the outer frame 14, and the liquid collection cavity 16 is located in the liquid collection housing 142. The liquid collection housing 142 may be connected to a bottom of the cover 141 through detachable connectors, such as bolts and screws.

It should be noted that the number of the support structure 17 may be two, and the two support structures 17 are provided on both sides of the outer frame 14 along a length direction, respectively. In order to form the guide slope 14211 for guiding the leaked liquid inside the liquid collection housing 142, a bottom surface of the support structure 17 may be configured to be inclined with respect to the guide slope 14211, in other words, the bottom surface of the support structure 17 is not parallel to the guide slope 14211. In this way, when the bottom surface of the support structure 17 is placed flat on a horizontal plane, the guide slope 14211 is inclined at a preset angle with respect to the horizontal plane, that is, the guide slope 14211 is inclined towards one side, so that the leaked liquid can flow down along the guide slope 14211, to realize liquid collection.

Specifically, the liquid collection housing 142 includes a bottom plate 1421 and an enclosing plate assembly 1422, where the guide slope 14211 is on the bottom plate 1421, the enclosing plate assembly 1422 is arranged on the bottom plate 1421, and the enclosing plate assembly 1422 is arranged to enclose an outer periphery of the guide slope 14211 to form the liquid collection cavity 16.

For example, for a rectangular guide slope 14211 (with four edges, namely a top edge, a bottom edge and two side edges), the bottom edge and the two side edges adjacent to the bottom edge of the guide slope 14211 may be each provided with an enclosing plate, that is, the liquid collection cavity 16 is defined by the guide slope 14211 together with the three enclosing plates. In this case, the enclosing plate assembly 1422 includes three enclosing plates.

In addition, the liquid collection housing 142 further includes a baffle plate 1423, which is arranged on the top edge of the guide slope 14211. The baffle plate 1423 and the enclosing plate assembly 1422 form a closed fence structure on the bottom plate 1421, thereby forming a liquid collection box structure or a liquid collection tray structure. An upper end of the liquid collection box structure is open for receiving the leaked liquid dropped from the accommodation cavity 15. The baffle plate 1423 is used to prevent the leaked liquid from splashing out of the outer frame 14 when falling onto the guide slope 14211, which may affect the operation safety of the server.

It should be noted that the so-called bottom and top edges of the guide slope 14211 are named based on an actual orientation of the outer frame 14 in an operation state. In the operation state, the bottom surface of the support structure 17 is placed flat on the horizontal plane, the guide slope 14211 is inclined at a preset angle with respect to the horizontal plane. In this case, the higher side of the guide slope 14211 is regarded as the top edge, and the lower side is regarded as the bottom edge.

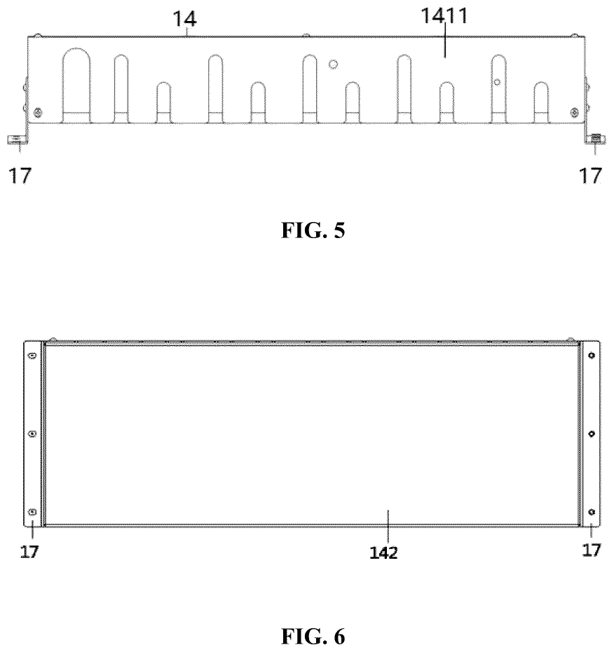

Referring to FIG. 5, the cover 141 is arranged to cover the liquid collection housing 142 from outside. The cover 141 includes a positioning plate assembly 1411, and the liquid supply pipe 12 and the liquid return pipe 13 pass through the positioning plate assembly 1411 to be positioned to the positioning plate assembly 1411. In an embodiment, the cover 141 covers the top and the periphery of the liquid collection housing 142 in an enclosing manner.

Correspondingly, a fixed plate may further be provided on a side opposite to the side where the positioning plate assembly 1411 is located, where the fixed plate is used to fixedly mount the liquid distributor and collector 11, and the liquid distributor and collector 11 is fixedly mounted on an inner side of the fixed plate.

In this embodiment, the positioning plate assembly 1411 includes a first positioning plate and a second positioning plate.

The first positioning plate may be connected to the liquid collection housing 142, for example, connected to the baffle plate 1423 by screws. The first positioning plate is provided with a first positioning groove and a second positioning groove each having an opening facing upward. The second positioning plate is provided with a third positioning groove and a fourth positioning groove each having an opening facing downward.

It should be noted that the second positioning plate and the first positioning plate abut against each other, so that the first positioning groove and the third positioning groove are staggered with respect to each other to form a liquid-supply positioning structure for positioning the liquid supply pipe 12, and the second positioning groove and the fourth positioning groove are staggered with respect to each other to form a liquid-return positioning structure for positioning the liquid return pipe 13.

Specifically, the first positioning groove, the second positioning groove, the third positioning groove, and the fourth positioning groove are all U-shaped grooves. The shape and structure of the liquid-supply positioning structure match the shape and structure of the liquid supply pipe 12; similarly, the shape and structure of the liquid-return positioning structure match the shape and structure of the liquid return pipe 13. The number of the first positioning groove, the second positioning groove, the third positioning groove, and the fourth positioning groove may be adjusted according to the actual number of the liquid supply pipe 12 and the liquid return pipe 13, which can ensure the positioning stability of the liquid supply pipe 12 and the liquid return pipe 13, and prevent vibrations of the liquid supply pipe 12 and the liquid return pipe 13 during the operation of the server, which not only ensures stable distribution of the liquid cooling medium in the liquid distributor and collector 11 but also effectively avoids leakage of the liquid cooling medium at weak positions of joints of the pipelines due to the vibration of the liquid supply pipe 12 and liquid return pipe 13, thereby greatly improving the operation security of the server.

In some embodiments, as shown in FIG. 3, the outer frame 14 is further provided with an observation window 1412, and the inner wall of the liquid collection housing 142 is provided with a liquid level indication line. The observation window 1412 is used to observe the liquid level indication line at a position of the leaked liquid is inside the liquid collection housing 142.

In this embodiment, the observation window 1412 is a transparent window, through which the amount of the leaked liquid inside the outer frame 14 can be directly observed, which is beneficial to timely deal with the leakage.

In some embodiments, the observation window 1412 is rotatably connected to the top of the outer frame 14, and the observation window 1412 can be flipped toward the outside of the outer frame 14 to form a maintenance opening for mounting and removing the liquid supply pipe 12 and the liquid return pipe 13.

That is, the observation window 1412 can serve as not only a window for observing the leakage amount in the outer frame 14 but also the maintenance opening for the liquid supply pipe 12 and the liquid return pipe 13. In this way, when the liquid distributor and collector 11 needs to be maintained, maintenance and replacement can be performed to the liquid distributor and collector 11 and the pipelines thereon through the maintenance opening, there's no need to remove the outer frame 14, which greatly improves the work efficiency.

In some embodiments, the liquid collection housing 142 is embodied as a liquid collection trough, which extends along an extension direction of the liquid supply pipe 12 and the liquid return pipe 13 on the liquid distributor and collector 11, in other words, the liquid collection trough extends along a length direction of the liquid distributor and collector 11. The liquid level indication line is provided on the inner wall of the liquid collection trough and includes a warning scale line.

The so-called warning scale line refers to a warning level of the amount of the leaked liquid inside the outer frame 14. When the amount the leaked liquid inside the outer frame 14 exceeds the warning scale line, the leaked liquid needs to be drawn out timely.

In some embodiments, the liquid distribution and collection module 1 further includes a liquid suction tube, a liquid suction assembly, a leakage detection sensor, and a control assembly. The liquid suction assembly may be a liquid suction pump, and the control assembly is electrically connected to the leakage detection sensor and the liquid suction assembly. The liquid suction assembly is connected to the liquid collection trough via the liquid suction tube, and the control assembly is used to control the liquid suction assembly to be started to draw the leaked liquid out of the liquid collection trough when the leaked liquid in the liquid collection trough exceeds the warning scale line.

It should be noted that in the present disclosure, the terms such as first and second are only used for distinguishing between similar parts and are not intended to describe a specific sequence or precedence order.

The liquid collecting device according to the present application is described in detail hereinbefore. The principle and the embodiments of the present application are illustrated herein by specific examples. The above description of examples is only intended to help the understanding of the method and the idea of the present application. It should be noted that, for those skilled in the art, a few of modifications and improvements may be made to the present application without departing from the principle of the present application, and these modifications and improvements are also deemed to fall into the scope of the present application defined by the claims.

1. A liquid distribution and collection module, comprising a liquid distributor and collector, and a liquid supply pipe and a liquid return pipe being connected to the liquid distributor and collector, wherein the liquid distribution and collection module further comprises an outer frame, and wherein
an accommodation cavity and a liquid collection cavity are provided in the outer frame;
the liquid distributor and collector, at least part of the liquid supply pipe, and at least part of the liquid return pipe are accommodated in the accommodation cavity; and
the liquid collection cavity is in communication with the accommodation cavity, to allow a leaked liquid in the accommodation cavity to be gathered into the liquid collection cavity.

2. The liquid distribution and collection module according to claim 1, further comprising a support structure being connected to the outer frame, wherein the support structure is configured to support the outer frame, to make a guide slope configured for guiding the leaked liquid be formed inside the outer frame.

3. The liquid distribution and collection module according to claim 2, wherein
the outer frame comprises a liquid collection housing, and the liquid collection cavity is formed in the liquid collection housing; and wherein the liquid collection housing comprises a bottom plate and an enclosing plate assembly, wherein
the guide slope is provided on the bottom plate, the enclosing plate assembly is arranged on the bottom plate, and the enclosing plate assembly is configured to enclose an outer periphery of the guide slope to form the liquid collection cavity.

4. The liquid distribution and collection module according to claim 3, wherein
the liquid collection housing further comprises a baffle plate, and the baffle plate and the enclosing plate assembly together form a closed fence structure on the bottom plate, to prevent the leaked liquid from splashing out of the outer frame.

5. The liquid distribution and collection module according to claim 3, wherein
the outer frame further comprises a cover being connected to the liquid collection housing; and wherein
the cover comprises a positioning plate assembly, the liquid supply pipe and the liquid return pipe pass through the positioning plate assembly to be positioned by the positioning plate assembly.

6. The liquid distribution and collection module according to claim 5, wherein the positioning plate assembly comprises a first positioning plate and a second positioning plate; and wherein
the first positioning plate is provided with a first positioning groove and a second positioning groove each having an opening facing upward;
the second positioning plate is provided with a third positioning groove and a fourth positioning groove each having an opening facing downward; and
the second positioning plate and the first positioning plate abut against each other, and the first positioning groove and the third positioning groove are staggered with respect to each other to form a liquid-supply positioning structure for positioning the liquid supply pipe, and the second positioning groove and the fourth positioning groove are staggered with respect to each other to form a liquid-return positioning structure for positioning the liquid return pipe.

7. The liquid distribution and collection module according to claim 3, wherein
the outer frame is further provided with an observation window, and an inner wall of the liquid collection housing is provided with a liquid level indication line; and
the observation window is configured to observe the liquid level indication line at a position of the leaked liquid inside the liquid collection housing.

8. The liquid distribution and collection module according to claim 7, wherein the observation window is rotatably connected to a top of the outer frame, and the observation window is configured to be flipped toward an outside of the outer frame to provide a maintenance opening for mounting and removing the liquid supply pipe and the liquid return pipe.

9. The liquid distribution and collection module according to claim 7, wherein the liquid collection housing is embodied as a liquid collection trough, and the liquid level indication line is provided on an inner wall of the liquid collection trough and comprises a warning scale line.

10. The liquid distribution and collection module according to claim 9, further comprising a liquid suction tube, a liquid suction assembly, a leakage detection sensor, and a control assembly; wherein
the control assembly is electrically connected to the leakage detection sensor and the liquid suction assembly, and the liquid suction assembly is connected to the liquid collection trough via the liquid suction tube, to control the liquid suction assembly to be started to draw the leaked liquid out of the liquid collection trough when the leaked liquid exceeds the warning scale line.
